(19) United States
(12) Patent Application Publication
(10) Pub. No.: US 2018/0342631 A1
(43) Pub. Date: Nov. 29, 2018

(54) SOLAR PANEL PROTECTIVE FILM

(71) Applicants: Fred A. KINGERY, New Wilmington, PA (US); Andrew N. KINGERY, Scott Township, PA (US)

(72) Inventor: Andrew N. KINGERY, Scott Township, PA (US)

(21) Appl. No.: 15/985,988

(22) Filed: May 22, 2018

Related U.S. Application Data
(60) Provisional application No. 62/509,964, filed on May 23, 2017.

(51) Int. Cl. H01L 31/0216; H02S 40/22

(52) U.S. Cl. CPC H01L 31/02167; H01L 31/02164; H02S 40/22

(57) ABSTRACT

A film is described for covering one or more radiation facing surfaces of a photo voltaic panel. The film provides a peel-away film to be applied to the surface of a solar panel that renders the solar panel inoperative up until the point that it is ready to be used. The film may be applied during manufacture of the solar panel (or at some other time prior to use of the solar panel), and remain on the solar panel throughout transport and installation of the solar panel. Once installed, electrically connected and tested, the film may be peeled off, exposing the solar panel only once it is ready to be used. Optionally, the film can be printed.

### FIELD

This invention relates to a solar panel protective film.

### BACKGROUND

Attention is increasingly being paid to regenerative energy sources. One method of sustainable energy production is solar technology, with which electricity can be obtained from photovoltaic cells from solar collectors.

Photo Voltaic (PV) panels come out of the shipping box ready to install and each PV cell generates a voltage the moment it is exposed to radiation in the visible spectrum. Commercially available panels do not typically include ON/OFF switches for individual solar panels.

The inability to switch off solar panels during installation may be a safety hazard for solar panel installers. As multiple solar panels are installed, the panels are connected in series strings. As the numbers of series strings increase so does the voltage being produced. Thus the risk of electric shock to installers increases with an increased number of solar panels. A further risk to installers is that the surface of solar panels may heat up to such an extent that an installer may be burnt upon contact with the solar panel. Electricity produced and/or extremely hot solar panel surfaces may also present a fire hazard.

The present invention may provide a film to address or at least ameliorate the problems described above, or at least provide the public with a useful choice.

### SUMMARY

According to one example embodiment there is provided a film for covering one or more radiation facing surfaces of a photo voltaic panel, the film including: i. a panel facing surface, wherein the panel facing surface is configured to self-adhere to the radiation facing surface; and ii. a solar radiation facing surface which substantially prevents the photovoltaic panel from activating whilst the film is adhered to the surface of the solar panel.

It is acknowledged that the terms “comprise”, “comprises” and “comprising” may, under varying jurisdictions, be attributed with either an exclusive or an inclusive meaning. For the purpose of this specification, and unless otherwise noted, these terms are intended to have an inclusive meaning—i.e., they will be taken to mean an inclusion of the listed components which the use directly references, and possibly also of other non-specified components or elements.

Reference to any document in this specification does not constitute an admission that it is prior art, validly combinable with other documents or that it forms part of the common general knowledge.

### BRIEF DESCRIPTION OF THE DRAWINGS

The accompanying drawings which are incorporated in and constitute part of the specification, illustrate embodiments of the invention and, together with the general description of the invention given above, and the detailed description of embodiments given below, serve to explain the principles of the invention, in which:

FIG. 1 is a perspective view of a solar panel;

FIG. 2 is a perspective view of a solar panel including film;

FIG. 3 is a perspective view of a solar panel including film which is partially peeled off;

FIG. 4 is a partial side view of film being peeled from a solar panel;

FIG. 5 is a perspective view of a solar panel including film;

FIG. 6 is a perspective view of a film roll;

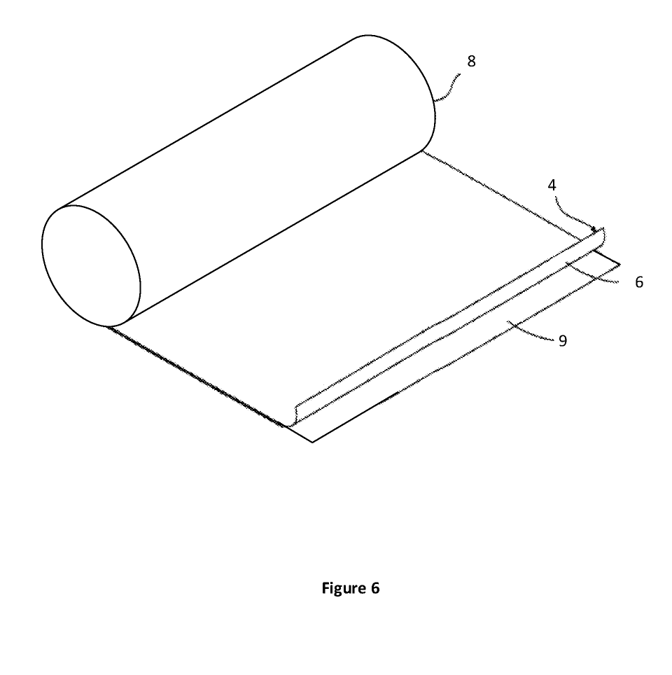

FIG. 7 is a side view of an applicator;

FIG. 8 is a side view of an applicator; and

FIG. 9 is a perspective view of an applicator.

### DETAILED DESCRIPTION

In general terms, embodiments may provide a peel-away film to be applied to the surface of a solar panel, in order to render the solar panel inoperative up until the point that it is ready to be used. The film may be applied during manufacture of the solar panel (or at some other time prior to use of the solar panel), and remain on the solar panel throughout transport and installation of the solar panel. Once installed, electrically connected and tested, the film may be peeled off, exposing the solar panel only once it is ready to be used.

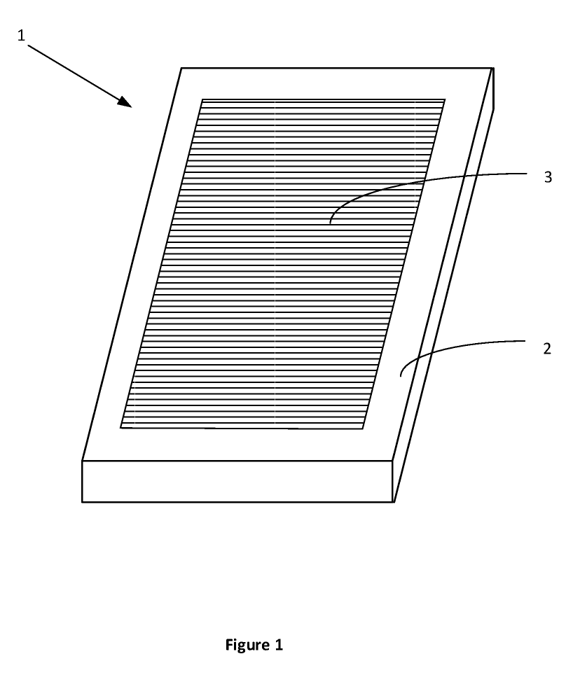

FIG. 1 illustrates a solar panel 1. The solar panel 1 has a frame 2 and an array of photovoltaic cells 3, covered by a glass surface. Other solar panel surfaces are also possible, such as acrylic or polymer solar panel surfaces. Whenever the panel 1 is exposed to solar radiation, the panel 1 is live and can potentially cause electrocution, particularly during the installation process when an array of solar panels are being connected to each other. In the context of this specification “solar radiation” refers to electromagnetic radiation given off by the Sun and includes radiation which may be produced from artificial sources (e.g. light bulbs that mimic the Sun's spectrum).

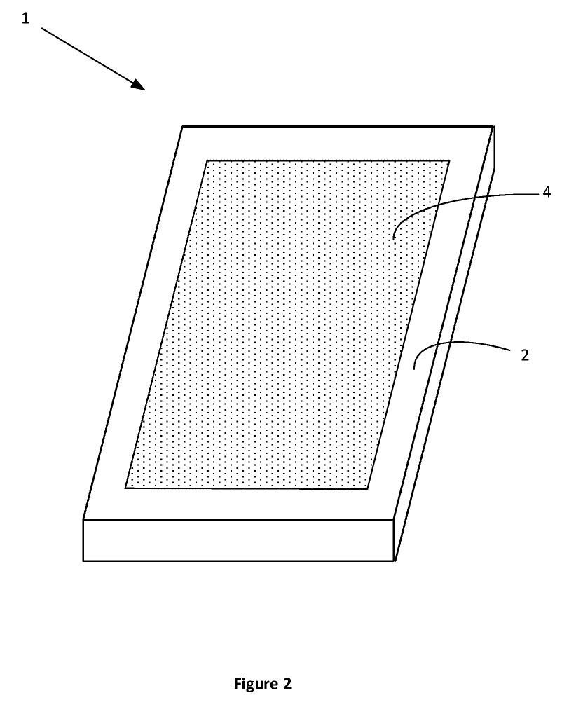

FIG. 2 illustrates a solar panel 1, including a film 4, covering the array of photovoltaic cells. As discussed in further detail below, the film 4 prevents solar radiation (e.g. light) from reaching the photovoltaic cells (not shown). This has the same effect as switching the solar panel off. The film 4 may partially cover or shade the photovoltaic cells enough, or in such a way, as to substantially prevent the photovoltaic panel from activating, to reduce or eliminate any voltage produced. “Activating” a photovoltaic panel means producing a voltage of over 50% of the nominal voltage.

For example, when the film covers the panel the voltage produced may be less than 10% of the nominal voltage.

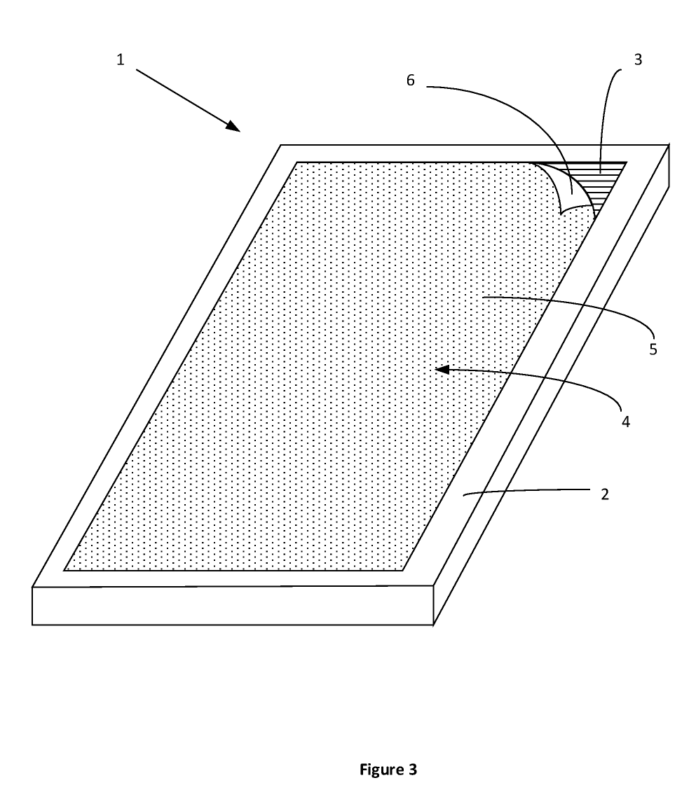

FIG. 3 shows a perspective view of the solar panel of FIG. 2, with the film 4 being slightly peeled off from the surface of the solar panel 1, exposing the photovoltaic cells 3. The film 4 has an exterior facing surface 5 and a solar panel facing surface 6.

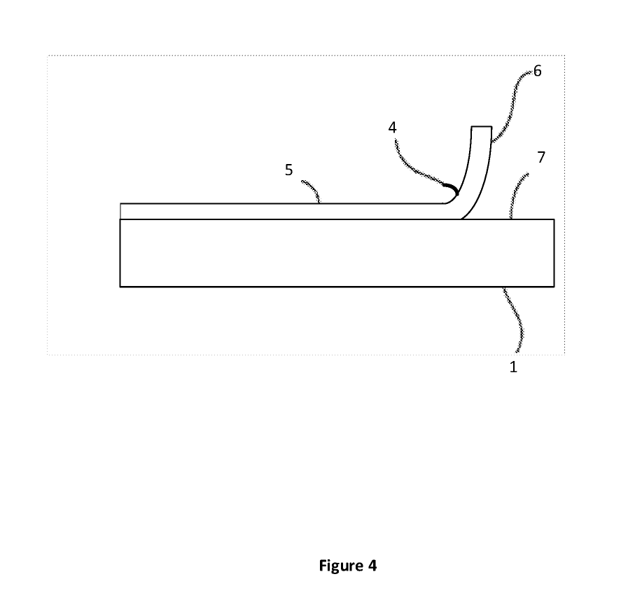

FIG. 4 shows a cross sectional partial side view of film 4 applied to a solar panel 1. The film 4 is slightly peeled off from a top surface 7 of the solar panel 1, revealing the solar panel facing surface 6.

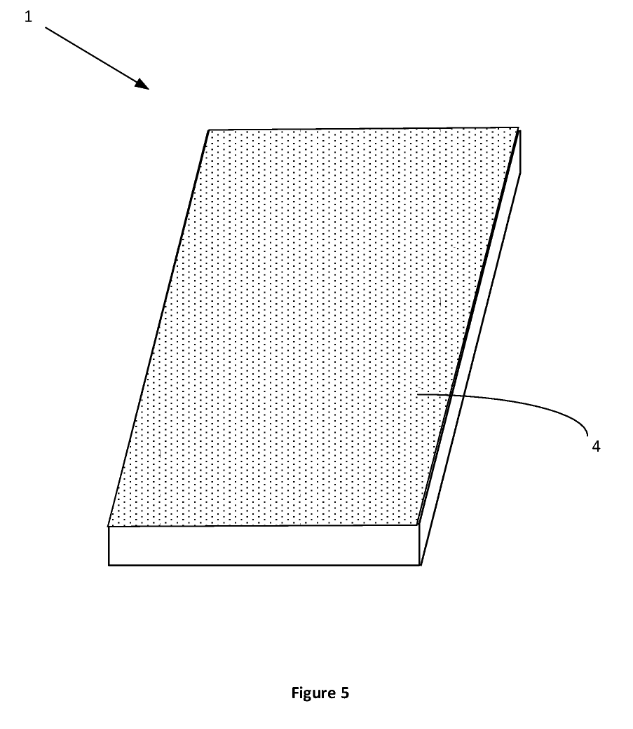

Coverage of the film may extend beyond the photovoltaic cells. For example, FIG. 5 shows an embodiment in which the film covers the entire top surface of the solar panel, including both the photovoltaic cells as well as the solar panel framing.

A key feature of the film is that it prevents solar radiation from reaching photovoltaic material of the solar panel when it covers the surface of the solar panel. The film preferably completely covers the energy conversion surface of the solar panel. However, even partly covering the energy conversion surface of the solar panel can improve safety.

The film may have any suitable structure and/or composition which achieves the purpose of blocking the transmission of solar radiation and adhering to a solar panel surface in an easily removable manner.

### Material Composition—Solar Radiation Blocking

Covering the solar panels with the film 1 renders the solar panels inoperative such that the panels present no real threat of DC electric shock while making electrical connections between solar panels, or connecting solar panel modules in series.

In order to effectively render the solar panel inoperable, the film is configured to prevent the transmission of photons to the photovoltaic cells of the solar panel.

To that effect, the film may reflect and/or absorb solar radiation wavelengths. At present, solar panels may be configured to create electricity from solar radiation with the wavelengths of between 400 nm to 1100 nm. However, the spectrum which solar panels create electricity from may vary in the future, e.g.: there may be full spectrum PV cells. The film is preferably configured to block radiation between 350 nm to 1200 nm.

As solar panels may be tuned to specific wavelengths of solar radiation, embodiments of the film may thus be tailored for a particular application. In other words, the film may be configured to prevent the transmission certain subsets of wavelengths of solar radiation.

The film may have a thickness of from 50 to 130 microns. In one embodiment, the film is a 100-micron thick film backed with a polyolefin base. The film may have a black solar panel facing surface, and a white or reflective exterior facing surface.

Any suitable material which blocks solar radiation may be used. As examples, the film may include a laminated structure of the reflective film adhered to a clear or dyed polyester film by which means the reflective metal is sandwiched between two layers of polyester film. In other embodiments, it can be a laminated structure of a reflective film to a polyolefin film.

The film can be a single sheet of polyester dyed sufficiently to absorb or reflect sunlight, or it can be a single sheet of polyester, on one side of which a reflective metal (such as aluminum) is deposited in an amount which can be totally reflective and over which a protective coating is deposited.

Any suitable color may be used for the exterior-facing surface of the film. A coloring agent may be included to that effect. For example, a white pigmentation or reflective surface may be used to protect the solar panel against overheating before the solar module is taken into operation. Alternatively, the color of the solar panel may be configured to reduce glare. Lighter colors have the advantage of reducing heating of the film/panel surface however result in higher glare. The color of the exterior-facing surface of the film may be customized to suit a particular customer's needs (e.g. to match a customer's branding)

### Material Composition—Adhesion

The film 4 may include pressure-sensitive adhesive properties, such that it forms a temporary bond to a solar panel surface and can be removed after months or years without leaving residue on the solar panel surface. Pressure sensitive adhesives are generally viscoelastic polymers with their rheology tuned to the desired bonding and de-bonding characteristics needed. Materials which may be used to make the film include (but are not limited to):
acrylate polymer
rubber, either natural rubber or synthetic thermoplastic elastomer
silicone rubber

The material may be blended with a tackifier to produce permanent tack (“grabbing power”) at room temperature, may be deformable, have a low surface energy, and moisture resistance.

To meet these requirements, these materials may have a low cross-linking density, low viscosity, and broad molecular weight distribution to enable deformation of the adhesive material to the substrate under various temperatures and peel conditions.

The film is easily removable from the surface. For example, the film may be peeled off when the panels are ready for operation. Preferably, the film peels off without leaving any residue, and without breaking or tearing.

The film may be configured to allow the printing of information on the exterior facing surface of the film. This allows a solar panel manufacturer or distributor to print a logo, advertising slogan and/or other marketing material on the top surface of the film, thus making a marketing statement on the panel. User instructions can also be printed on the exterior surface of the film.

Since some time may elapse between the installation of the solar module and its being taken into operation, the film is preferably resistant to weathering, so as not to become brittle or to leave adhesive residues behind when it is removed. The film 4 may be configured to withstand long exposure to sunlight and UV radiation without significant degradation. The film may include a UV stabilizer to that effect. The film may include heat and/or moisture resistance properties. The film may also prevent damage to the PV panel, and/or prevent the accumulation of dust or other contaminants.

The film may be formed of a single layer, which includes all desired properties. For example, the film may comprise a single material which is self-adhesive and blocks solar radiation transmission. In other embodiments, the film may comprise two or more layers, each including one or more desired properties of the film. For example, the solar-panel facing surface of the film may comprise an adhesive layer, and the exterior facing surface of the film may comprise a solar radiation-reflective and/or absorbent layer.

### Release Coating

The exterior-facing surface of the film may be coated with a release agent that prevents the film from strongly adhering to itself, e.g. when in a roll, or attached to itself.

In other embodiments, prior to application, the film may include a release liner, which is a suitable film sheet (usually applied during the manufacturing process) used to prevent the film from prematurely adhering. The release liner may be paper, plastic or any other suitable material.

### Method of Manufacture of Film

The film may be manufactured in any suitable manner, depending on its structure and/or composition. Polymer-based films may be manufactured by coating or extrusion.

Coating consists of applying a thin coat of adhesive onto a polyethylene (PE) support. The resulting product is tear resistant to allow easy, one-piece removal by the final customer. The film may be specially engineered to withstand outdoor exposure.

Co-extrusion includes pushing molten plastic material into a multi-layer die to form a thin film. To obtain an adhesive coextruded product, material with an adhesive property is included in one of the outer layers.

### Method of Installation of Film

The film may be adhered to solar panels manually or mechanically.

The film may be provided in rolls. FIG. 5 shows a perspective view of a roll 8 of film 4 according an embodiment in which the film 4 includes a release liner 9 which is removed before the solar-panel facing surface 6 of the film 4 is adhered to the surface of a solar panel.

A user may manually unroll and cut off a desired length of film to be applied to a solar panel. A custom roller may be provided with an integrated cutter and/or a mechanism for unrolling predefined lengths.

Another embodiment of the invention provides film in sheets, which may be sized to fit standard solar panels, or cut to a desired shape and/or size.

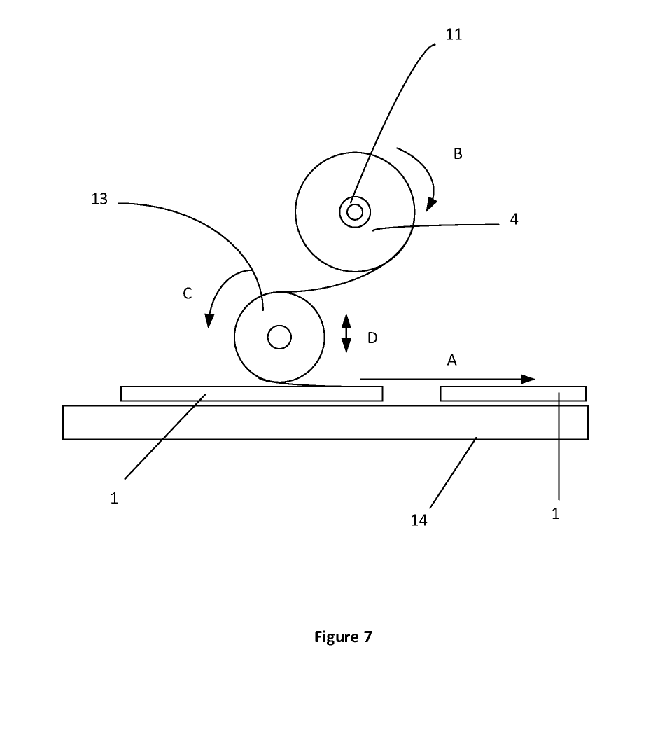

FIGS. 7 to 9 show mechanisms for mechanically and/or automatically applying film to the surface of solar panels.

The film may be applied as part of a solar panel production line. For example, a film-unrolling module may be included in a solar-panel manufacture factory or added to a solar-panel manufacture conveyor.

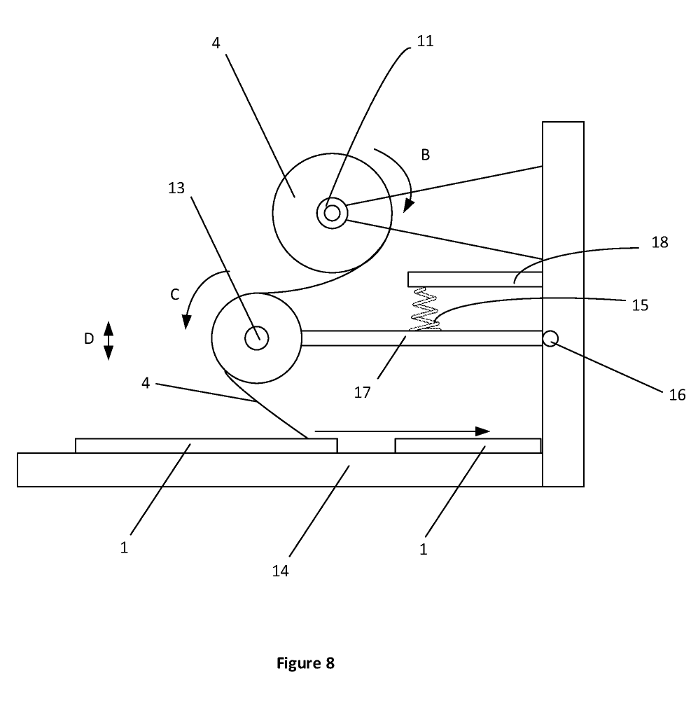

FIG. 7 shows a film applicator. In this embodiment the film has no release liner. The applicator includes a film roller 11 and an applicator roller 3. The film roller 11 and the application roller 13 rotate in opposite directions to release film. In the embodiment shown in FIG. 8, the panels 1 are moving on a conveyor 14 in the direction of Arrow A. The film roller 11 rotates in a clockwise direction B to release film and the applicator 13 rotates in a counter-clockwise direction to release the film onto the panels 1. The applicator roller 13 may move up and down as indicated by arrow D to apply film to each solar panel 1.

FIG. 8 shows a film applicator according to an embodiment in which the applicator is moved up and down and is attached to a spring 15. A stationary film roll holder 11 is positioned above a conveyor assembly line 14. A film 4 roll is mounted onto the holder.

An applicator roller 13 is mounted on a pivoting arm 17 below or adjacent the stationary film roll 11. The application roller 13 may comprise rubber or silicone so that it has firmness but enough give so as to be able to apply good pressure but not damage the solar panels 1.

A user may pre-feed the film from the stationary roll holder down to the applicator roller. The applicator roller may include a “tacky” quality such that the film adheres to it, but not so much that it sticks to the roll instead of the panel surface.

The applicator roll 13 is able to move up and down in the direction of arrows D so as to apply the film to the surface of the solar panel 1 and then move up out of the way (stop applying pressure) once the length of the solar panel has been covered.

The film may be pre-perforated from the film manufacturer. The length of each section may be configured to suit a specific solar panel length. This may be predetermined by solar panel manufacturer for the length of their specific panels. For example, perforations may be spaced by 50″ to 70″ inches. After the length of the panel is covered in film, the applicator roll will lift up and the perforations can be cut manually or automatically.

The applicator roller can either be moved up and down by hand via the spring 15. A user may pull the applicator roller 13 down and apply the pressure to sufficiently apply the film, therefore stretching the spring, and then the spring would lift the roller up once the user releases the downward pressure.

This process could also be automated by a computer controlled pneumatic or hydraulic piston (or any other suitable arrangement) in lieu of the spring and manual handle.

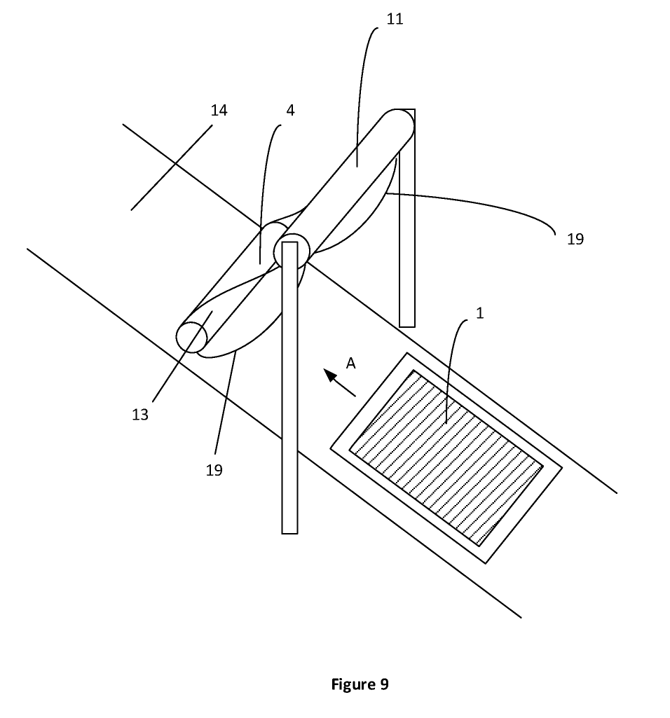

FIG. 9 shows another embodiment of a film applicator. In this embodiment, automated sliding track system via chain/belt 19 may move the applicator roll up and down.

The entire applicator set up may be mounted directly above a conveyor belt which feeds panels underneath the rolls. The applicator may be positioned at the end of the solar panel manufacturing assembly line.

### Method of Removal of Film

Once the one or more solar panels are installed, the films are pulled away from the working surface of the solar panel, leaving the photovoltaic cells exposed and free from scratches and dirt.

The film may include one or more features to make it easier to peel off. For example, one corner of the film may be non-adhesive to allow easy peel-off.

In some embodiments, multiple segments of film may be used to collectively cover a solar panel. Film segments may overlap. An overlapping section may be specifically included to facilitate removal of the film. A non-adhesive “tab” may be provided, protruding from a corner of the film to allow easy removal of the film and avoid possible user injury from a hot solar-panel surface.

In some embodiments, the film may be configured to be re-usable. In other words, once the film is removed from the solar panel surface, it can be reapplied to the same or another solar panel repeatedly without losing its adhesive properties.

Embodiments of the invention have until now been discussed in terms of use of the film prior to a first use of a solar panel, e.g. during transport and installation. However, the film may be applied to already-installed solar panels after they are installed. It may be desirable, for some reason or another, for solar panels to cease producing electricity (either temporarily or permanently) after they have been installed. For example, if maintenance, removal, rewiring, or changing the location of solar panels is required, the film can be applied to the solar panels to render them safer.

The film may be used on any suitable solar panel, including but not limited to Photovoltaic & Amorphous Solar Cells, Multi-layer Amorphous Solar Panels, or Full-Spectrum Photovoltaic Material. The film may be applied to solar panels produced from crystalline silicon solar cells, or thin-film technologies using cadmium telluride, CIGS and amorphous silicon. In other embodiments, the film may be adapted to other solar panel surface compositions, such as roofing tiles, roofing shingles and transparent colorless fluoropolymers used in flexi-solar panels.

### Benefits

There is thus provided an improved film for covering the surface of a solar panel, with the following benefits (amongst others):
The film reduces safety hazards presented by solar panels, including the risk of electric shock, burns, and/or fires.
The surface of module is protected from scratching/marring and kept clean during the entire transport and installation process, for optimal electricity production upon removal.
The film allows advertising material and/or instructions to be printed on the surface of solar panels prior to their installation.

While the present invention has been illustrated by the description of the embodiments thereof, and while the embodiments have been described in detail, it is not the intention of the Applicant to restrict or in any way limit the scope of the appended claims to such detail. Additional advantages and modifications will readily appear to those skilled in the art. Therefore, the invention in its broader aspects is not limited to the specific details, representative apparatus and method, and illustrative examples shown and described. Accordingly, departures may be made from such details without departure from the spirit or scope of the Applicant's general inventive concept.

1. A film for covering one or more radiation facing surfaces of a photo voltaic panel, the film including:
i. a panel facing surface, wherein the panel facing surface is configured to self-adhere to the radiation facing surface of the photo voltaic panel; and
ii. a radiation facing surface which substantially prevents the photovoltaic panel from activating whilst the film is adhered to the radiation facing surface of the photo voltaic panel.

2. The film of claim 1 wherein the radiation facing surface of the film is configured to block solar radiation between 350 nm to 1200 nm.

3. The film of claim 1 wherein the film includes a reflective layer capable of blocking radiation.

4. The film of claim 1 wherein the film includes an absorbent layer capable of blocking radiation.

5. The film of claim 1 wherein the radiation facing surface of the film comprises a polymer.

6. The film of claim 1 wherein the film has a thickness from 50 to 130 microns.

7. The film of claim 1 wherein the film is configured to peel off from the panel without leaving residue.

8. The film of claim 1 wherein the film is printable.

9. A method of reducing electricity produced by a solar panel, wherein the method includes the step of applying a film to a radiation facing surface of the solar panel, wherein the film substantially prevents the solar panel from activating whilst the film is adhered

10. A film for covering one or more radiation facing surfaces of a photo voltaic panel, the film comprising a polymer and having a thickness from 50 to 130 microns, the film further including:
i. a panel facing surface, wherein the panel facing surface is configured to self-adhere to the radiation facing surface of the photo voltaic panel; and
ii. a radiation facing surface configured to block solar radiation between 350 nm to 1200 nm surface which substantially prevents the photovoltaic panel from activating whilst the film is adhered to the radiation facing surface of the photo voltaic panel.

11. The film of claim 10 wherein the film is printable.

12. The film of claim 10 wherein the film is configured to peel off from the panel without leaving residue.
